(19) United States
(12) Patent Application Publication
(10) Pub. No.: US 2019/0080890 A1
(43) Pub. Date: Mar. 14, 2019

(54) VACUUM DEPOSITION COMPOSITE TARGET

(71) Applicant: Metal Industries Research and Development Centre, Kaohsiung (TW)

(72) Inventors: Cheng-Yen Wu, Kaohsiung (TW); Sung-Mao Chiu, Pingtung City (TW); Chao-Hsien Lin, Kaohsiung (TW); Ting-Pin Cho, Kaohsiung (TW); Jyh-Nan Shieh, Kaohsiung (TW); Chia-Hung Huang, Kaohsiung City (TW)

(21) Appl. No.: 15/855,221

(22) Filed: Dec. 27, 2017

(30) Foreign Application Priority Data
Sep. 14, 2017 (TW) 106131519

(51) Int. Cl. H01J 37/34; C23C 14/34; C23C 14/14

(52) U.S. Cl. CPC H01J 37/3435; C23C 14/3464; H01J 37/3426; H01J 37/3417; C23C 14/14

(57) ABSTRACT

A vacuum deposition composite target includes a plurality of target blocks each including a target body, an insulating layer and a high-resistance-conductive layer. The target body has a top surface, a bottom surface and a peripheral surface connected between the top and bottom surfaces. The insulating layer is formed on the peripheral surface. The high-resistance-conductive layer is formed on the bottom surface of the target body and has a resistance higher than that of the target body. The target blocks are juxtaposed to each other. Each of the target blocks has a modulated resistance. A modulated resistance difference between any two adjacent ones of the target blocks is not greater than 5%.

### CROSS-REFERENCE TO RELATED APPLICATION

This application claims priority of Taiwanese Invention Patent Application No. 106131519, filed on Sep. 14, 2017.

### FIELD

The disclosure relates to a vacuum deposition composite target, and more particularly to a vacuum deposition composite target including a high-resistance-conductive layer.

### BACKGROUND

Vacuum deposition is widely used in the field of surface machining to deposit layers on a surface of an article for improving appearance or surface properties thereof. With development of the vacuum deposition techniques, various types of materials for vacuum deposition have been used and tested, and deposited coating is demanded to have enhanced performance and quality. A great effort has been spent on formation of a uniform deposited coating with a relatively large area.

Conventional sputtering targets used for the vacuum deposition, such as melted alloy targets and sintered powder metallurgy targets, involve mixing different metal elements used for forming the deposited coating to form a single target, followed by conducting the vacuum deposition. However, melting and forging of multiple metal elements for making the melted alloy targets are relatively difficult, and the conventional sputtering targets thus formed have a relatively small bombarded surface unsuitable for mass production. On the other hand, manufacturing cost of the sintered powder metallurgy targets is relatively high.

Besides, analyzing the relationship of relevant parameters between compositions of the conventional sputtering targets and the deposited coating thus formed is time-consuming. The composition of the conventional sputtering targets may change overtime after the vacuum deposition has been carried out, which leads to unstable quality of the deposited coating. In addition, during the vacuum deposition, the higher the resistance of the conventional sputtering target, the easier it is for ions for bombarding the conventional sputtering target to be accumulated on the surface thereof. However, increase in the accumulated ions on the surface of the conventional sputtering target results in variation in velocity of subsequently generated ions to bombard the surface of the conventional sputtering target. Thus, the composition of the deposited coating produced using more of the conventional sputtering targets will deviate from a predetermined composition result and is difficult to be precisely controlled.

For alleviating the abovementioned problem, Taiwanese Invention Patent Application Publication No. 201024441 A1 discloses a target material including a plurality of coating material units. The target material may have a rectangular shape, where the coating material units are stripe-shaped and periodically arranged in a row, or have a disc shape, where the coating material units are circular sector-shaped and periodically arranged to form a complete circle. The target material is adapted for depositing a metal glass film with relatively large area and thickness and with a uniform composition. However, the problem that the composition of the deposited coating deviates from a predetermined composition result due to difference in resistances of the sputtering targets still cannot be satisfactorily solved. There is still a need in the art to pursue sputtering targets that permit precise control of the composition of the deposited layer thus formed.

### SUMMARY

Therefore, an object of the disclosure is to provide a vacuum deposition composite target that can alleviate at least one of the drawbacks of the prior art.

According to the disclosure, the vacuum deposition composite target includes a plurality of target blocks, each of which includes a target body, an insulating layer, and a high-resistance-conductive layer.

The target body has a top surface, a bottom surface opposite to the top surface and a peripheral surface connected between the top surface and the bottom surface.

The insulating layer is formed on the peripheral surface and surrounds the target body.

The high-resistance-conductive layer is formed on the bottom surface of the target body and has a resistance higher than that of the target body.

The target blocks are juxtaposed to each other in such a manner that the peripheral surfaces are adjacent to each other.

Each of the target blocks has a modulated resistance modulated by the high-resistance-conductive layer. A modulated resistance difference between any two adjacent ones of the target blocks is not greater than 5%.

### BRIEF DESCRIPTION OF THE DRAWINGS

Other features and advantages of the disclosure will become apparent in the following detailed description of the embodiment with reference to the accompanying drawings, of which:

FIG. 1 is a schematic top view of an embodiment of a vacuum deposition composite target according to the disclosure; and

FIG. 2 is a fragmentary schematic cross-sectional view taken along line II-II of FIG. 1.

### DETAILED DESCRIPTION

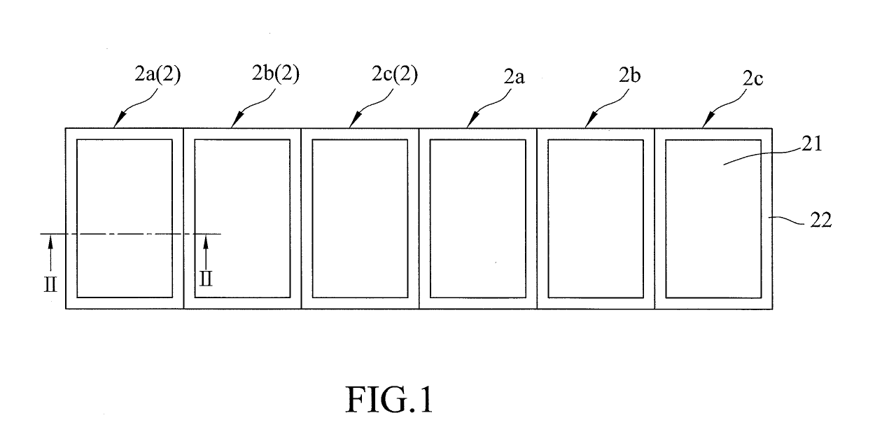

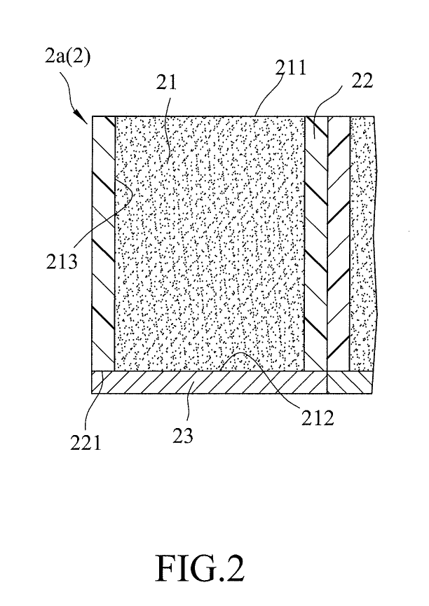

Referring to FIGS. 1 to 2, an embodiment of the vacuum deposition composite target according to the disclosure is illustrated. The vacuum deposition composite target may be used for physical vapor deposition and includes a plurality of target blocks 2. Each of the target blocks 2 includes a target body 21, an insulating layer 22, and a high-resistance-conductive layer 23.

The target body 21 of each of the target blocks 2 has a top surface 211, a bottom surface 212 opposite to the top surface 211, and a peripheral surface 213 connected between the top surface 211 and the bottom surface 212. In the embodiment, the target bodies 21 of the target blocks 2 have different resistances.

More specifically, the target bodies 21 of the target blocks 2 may be made from a target material selected from metals, alloys, and semiconductors. For example, the target bodies 21 may be made from aluminum (Al) or tungsten (W). In one form, a sputtering yield of the target material of the target body 21 of each the target block 2 is proportional to an area of the top surface 211 of the target body 21.

The insulating layer 22 of each of the target blocks 2 is formed on the peripheral surface 213 and surrounds the target body 21, and may be made from a heat-resistant and electrically insulating material selected from aluminum nitride, silicon, etc.

The high-resistance-conductive layer 23 of each of the target blocks 2 is formed on the bottom surface 212 of the target body 21 and has a resistance higher than that of the target body 21.

The target blocks 2 are juxtaposed to each other in such a manner that the peripheral surfaces 213 of the target bodies 21 are adjacent to each other.

Each of the target blocks 2 has a modulated resistance modulated by the high-resistance-conductive layer 23. A modulated resistance difference between any two adjacent ones of the target blocks 2 is not greater than 5%.

In detail, with formation of the high-resistance-conductive layers 23 of the relatively high resistance, the resistances of the target blocks 2 are wholly increased, and thus, the modulated resistance difference between the any two adjacent ones of the target blocks 2 is decreased. In other words, the target blocks 2 have similar modulated resistances.

In one form, the high-resistance-conductive layer 23 of each of the target blocks 2 has a resistance value that is at least three orders of magnitude greater than that of the target body 21, where the order of magnitude is defined by a power of ten. Alternatively, the resistance value of the high-resistance-conductive layer 23 of each of the target blocks 2 may be four orders of magnitude greater than that of the target body 21.

In one form, the high-resistance-conductive layer 23 may be made from a material selected from conductive ceramic, conductive metal oxides, conductive pastes, and semiconductors. More specifically, the material of the high-resistance-conductive layer 23 is selected from the group consisting of titanium nitride (TiN), chromium nitride (CrN), indium tin oxide (ITO), aluminum-doped zinc oxide (Al-doped ZnO), gallium-doped zinc oxide (Ga-doped ZnO), and silver paste.

In addition to selection of the material for making the high-resistance-conductive layer 23 as mentioned above, the resistance of the high-resistance-conductive layer 23 may be also adjusted by varying a thickness thereof.

In one form, the target blocks 2 include 1^{st} to n^{th} target blocks 2, where n is a positive integer not less than 2. The 1^{st} to n^{th} target blocks 2 are periodically arranged in series along a predetermined direction. In one form, the 1^{st} to n^{th} target blocks 2 are arranged as a rectangle, a disc, a checkerboard, or multiple concentric annular rings in shape. In addition, the insulating layer 22 of each of the target blocks 2 may have a bottom surface 221 coplanar with the bottom surface 212 of the target body 21, and the high-resistance-conductive layer 23 may be formed on the bottom surface 212 of the target body 21 and the bottom surface 221 of the insulating layer 22. In one form, the high-resistance-conductive layers 23 of the target blocks 2 may be formed on the bottom surfaces 212 of the target bodies 21 and the bottom surfaces 221 of the insulating layers 22 in a continuous and integral manner or in an individual and manner. Furthermore, in the embodiment, the vacuum deposition composite target has six of the target blocks 2, i.e., n is 6. The six target blocks 2 are made from three different kinds of the target materials and are grouped into two groups. Each of the groups includes one first type target block 2a, one second type target block 2b and one third type target block 2c. The two groups are juxtaposed arranged so that the target blocks 2a, 2b, 2c are arranged periodically as the rectangle in shape.

When the vacuum deposition composite target of the disclosure is used in the vacuum deposition, the vacuum deposition composite target is first disposed at a cathode located inside a chamber, and an object (not shown) that is to be deposited with a coating is disposed at an anode located inside the chamber and above the cathode. Subsequently, the chamber is vacuumed, and an inert gas is then introduced into the vacuum chamber. Thereafter, the anode and the cathode are electrically connected to a power supply to be applied with a high voltage, so as to generate an electric discharge. Ions generated in the electric discharge are then spouted to the cathode to bombard a top surface of the vacuum deposition composite target, so that sputtering particles are ejected from the top surface of the vacuum deposition composite target and then are deposited on a surface of the object to form a deposited coating.

By virtue of inclusions of the insulating layers 22 formed on the peripheral surfaces 213 of the target bodies 21 of the target blocks 2 and the high-resistance-conductive layers 23 formed on the bottom surfaces 212 of the target bodies 21, the modulated resistances of the target blocks 2 can be modulated by the high-resistance-conductive layers 23. Therefore, the difference in modulated resistance between any two adjacent ones of the target blocks 2 is decreased, and deviation from a composition of the deposited coating from an expected result can be alleviated.

In the following, decrease in the modulated resistance difference between any two adjacent ones of the target blocks 2 is described.

Given as an example, two of the target bodies 21 of the same shape are prepared. Each of these two target bodies 21 has a thickness of 5 mm. One of the target bodies 21 is made from aluminum (Al), and the other one of the target bodies 21 is made from tungsten (W). The bottom surfaces 212 of these two target bodies 21 are respectively formed with the high-resistance-conductive layers 23 made from titanium nitride (TiN) and have a thickness of 2 μm (2000 nm) so as to obtain two of the target blocks 2 based on the target body 21 of Al and the target body 21 of W, respectively.

It is noted that Al has an electrical resistivity of 2.82×10⁻¹⁰ Ω-cm, W has an electrical resistivity of 5.6×10¹⁰ Ω-cm, and TiN has an electrical resistivity of 1×10⁻⁴ Ω-cm. Since the target body 21 of Al and the target body 21 of W have the same shape and since the insulating layers 22 respectively formed on the peripheral surfaces 213 of the target body 21 of Al and the target body 21 are relatively thin, the target body 21 of Al and the target body 21 of W have a cross-sectional area substantially the same as that of the high-resistance-conductive layers 23. Hence, the product of the electrical resistivity of Al and the thickness of the target body 21 of Al is in proportion to the resistance of the target body 21 of Al, the product of the electrical resistivity of W and the thickness of the target body 21 of W is in proportion to the resistance of the target body 21 of W, and equivalent thicknesses of the TiN high-resistance-conductive layers 23 that respectively correspond to the resistances of the target body 21 of Al and the target body 21 of W can be calculated based on the electrical resistivity of the high-resistance-conductive layers 23 of TiN. Specifically, the target body 21 of Al is equivalent to the high-resistance-conductive layer 23 of TiN having the thickness of about 14 nm (i.e., 5×10⁶ nm×2.82×10⁻¹⁶ Ω-cm=14.1 nm×1×10⁻⁴ Ω-cm), and the target body 21 of W is equivalent to the high-resistance-conductive layer 23 of TiN having the thickness of 28 nm (i.e., 5×10⁶ nm×5.6×10⁻¹⁶ Ω-cm=28 nm×1×10⁻⁴ Ω-cm). An equivalent resistance ratio of the target body 21 of Al to the target body 21 of W is determined to be 0.5 by dividing the thickness of the high-resistance-conductive layers 23 of TiN equivalent by the target body 21 of Al to the thickness of the high-resistance-conductive layers 23 of TiN equivalent to the target body 21 of W (i.e., 14 nm/28 nm).

In order to compare the modulated resistance of the target blocks 2 respectively based on the target body 21 of Al and the target body 21 of W, the modulated resistance of each of the target blocks 2 is represented in terms of the thickness of the high-resistance-conductive layer 23 which has the resistance equivalent to modulated resistance. Thus, the modulated resistance of the target block 2 including the target body 21 of Al, which is equivalent to 14 nm of the high-resistance-conductive layer 23, and the high-resistance-conductive layer 23 of 2000 nm is 2014 nm, whereas the modulated resistance of the target block 2 including the target body 21 of W, which is equivalent to 28 nm of the high-resistance-conductive layer 23, and the high-resistance-conductive layer 23 of 2000 nm is 2028 nm. The ratio of the modulated resistance of the target block 2 based on the target body 21 of Al to the modulated resistance of the target block 2 based on the target body 21 of W is about 0.993 (i.e., 2014/2028). The result shows that the modulated resistances of these two target blocks 2 are similar and specifically, the difference between the modulated resistances of these two target blocks 2 is not greater than 5%.

With respective formation of the high-resistance-conductive layers 23 on the bottom surfaces 212 of the target bodies 21, the resistance of the target blocks 2 can be easily adjusted, and the modulated resistance difference of any two adjacent ones of target blocks 2 can be precisely controlled within a desired range. Hence, uniformity and accuracy of the composition of the deposited coating formed using the vacuum deposition composite target of the disclosure can be improved.

In the description above, for the purposes of explanation, numerous specific details have been set forth in order to provide a thorough understanding of the embodiment. It will be apparent, however, to one skilled in the art, that one or more other embodiments may be practiced without some of these specific details. It should also be appreciated that reference throughout this specification to appreciated tha, “specification t,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects.

While the disclosure has been described in connection with what is considered the exemplary embodiment, it is understood that this disclosure is not limited to the disclosed embodiment but is intended to cover various arrangements included within the spirit and scope of the broadest interpretation so as to encompass all such modifications and equivalent arrangements.

What is claimed is:

1. A vacuum deposition composite target, comprising a plurality of target blocks, each of said target blocks including:
a target body having a top surface, a bottom surface opposite to said top surface, and a peripheral surface connected between said top surface and said bottom surface;
an insulating layer formed on said peripheral surface and surrounding said target body; and
a high-resistance-conductive layer formed on said bottom surface of said target body and having a resistance higher than that of said target body,
wherein said target blocks are juxtaposed to each other in such a manner that said peripheral surfaces of the target bodies are adjacent to each other; and
wherein each of said target blocks has a modulated resistance modulated by said high-resistance-conductive layer, a modulated resistance difference between any two adjacent ones of said target blocks is not greater than 5%.

2. The vacuum deposition composite target of claim 1, wherein said high-resistance-conductive layer of each of said target blocks has a resistance value that is at least three orders of magnitude greater than that of said target body, where the order of magnitude is defined by a power of ten.

3. The vacuum deposition composite target of claim 1, wherein said target blocks include 1^{st} to n^{th} target blocks, where n is a positive integer not less than 2, said 1^{st} to n^{th} target blocks being periodically arranged in series along a predetermined direction.

4. The vacuum deposition composite target of claim 1, wherein a sputtering yield of a target material of said target body is proportional to an area of said top surface said target body.

5. The vacuum deposition composite target of claim 1, wherein said target bodies of said target blocks are made from a target material selected from metals, alloys, and semiconductors.

6. The vacuum deposition composite target of claim 3, wherein said target bodies of said 1^{st} to n^{th} target blocks are made from different target materials.

7. The vacuum deposition composite target of claim 1, wherein said high-resistance-conductive layer of each of said target blocks is made from a material selected from conductive ceramics, conductive metal oxides, conductive pastes, and semiconductors.

8. The vacuum deposition composite target of claim 7, wherein the material of said high-resistance-conductive layer is selected from the group consisting of titanium nitride (TiN), chromium nitride (CrN), indium tin oxide (ITO), aluminum-doped zinc oxide (Al-doped ZnO), gallium-doped zinc oxide (Ga-doped ZnO), and silver paste.

9. The vacuum deposition composite target of claim 1, wherein said insulating layer of each of said target blocks has a bottom surface coplanar with said bottom surface of said target body, said high-resistance-conductive layer being formed on said bottom surface of said target body and said bottom surface of said insulating layer.
